(19) United States
(12) Patent Application Publication
(10) Pub. No.: US 2013/0295384 A1
(43) Pub. Date: Nov. 7, 2013

(54) Transparent Electrode with Flexibility and Method for Manufacturing the Same

(71) Applicant: TAIWAN TEXTILE RESEARCH INSTITUTE, New Taipei City (TW)

(72) Inventors: Chen-Chi M. Ma, Hsinchu City (TW); Yuan-Li Huang, Hsinchu City (TW); Shin-Yi Yang, Hsinchu City (TW); Hsi-Wen Tien, Hsinchu City (TW)

(73) Assignee: TAIWAN TEXTILE RESEARCH INSTITUTE, New Taipei City (TW)

(21) Appl. No.: 13/668,653

(22) Filed: Nov. 5, 2012

(30) Foreign Application Priority Data
May 3, 2012 (TW) 101115776

(51) Int. Cl. D01F 9/00; C23C 14/35; B05D 5/12; B05D 1/16; B32B 27/02; B32B 9/04; B82Y 30/00

(52) U.S. Cl. 428/368; 204/192.29; 427/122; 427/462; 977/734; 977/762

(57) ABSTRACT

A transparent electrode and method for manufacturing the same are disclosed. The major integrants of the transparent electrode comprise a graphene and a nanofiber. The nanofiber exhibits a light-permeable network structure to increase the light transmittance of the transparent electrode. The graphene is absorbed on the surface of the nanofiber to form a conductive light-permeable network structure. And the unique properties of the graphene lead an improvement of the mechanical strength property of the transparent electrode.

### RELATED APPLICATIONS

This application claims priority to Taiwan Application Serial Number 101115776, filed May 3, 2012, which is herein incorporated by reference.

### BACKGROUND

1. Technical Field

The present disclosure relates to a transparent electrode and a method for manufacturing the same, and more particularly, to a transparent electrode with flexibility and a method for manufacturing the same.

2. Description of Related Art

Transparent electrodes have been widely used in information and electronic products, such as in display panels of mobile phones or tablet PCs. Because the indium tin oxide (ITO) has excellent electric conductivity and light transmittance, the ITO is often used as a transparent electrode in the art. In spite of having the above advantages, the ITO is brittle and apt to be fractured due to lack of elasticity.

Graphene has a layered structure, and possesses properties of conductivity, chemical resistance and high mechanical strength. Therefore, in the recent study, graphene has been used to replace the ITO as new transparent conductive materials. However, in reducing the surface resistance of the graphene, the thickness of the graphene must be increased, which makes the transparent electrode of the graphene dimmed and reduces the light transmission of the transparent electrode.

Therefore, to promote the development of information and electronic industries, there are needs in the industries to seek alternative materials with high conductivity, high transmittance and flexibility.

### SUMMARY

The present disclosure provides a composite structure for a transparent electrode. According to one embodiment of the present disclosure, the composite structure includes a nanofiber substrate, a graphene layer, and an organic compound. The nanofiber substrate has a light-permeable plane net structure. The graphene layer is formed on the surface of the light-permeable plane net structure of the nanofiber substrate, and the graphene layer includes one or more layers of graphene overlapping to each other. The organic compound is formed between the nanofiber substrate and the graphene layer, and has at least a functional group selected from the group consisting of phenyl, pyridyl, pyrimidinyl, carbazolyl, imidazolyl, pyrrolyl, pyrrolidinyl, pyrrolidone, hydroxyl, carbonyl, amine, secondary amine, tertiary amine, fluorine atoms and a combination thereof. The organic compound is used to increase the adhesive interaction between the graphene layer and nanofiber substrate, in order to avoid disconnection caused by the shedding of the graphene layer.

According to one embodiment of the present disclosure, the nanofiber substrate is a material including Nylon 66, polyurethane, or polystyrene.

According to one embodiment of the present disclosure, the organic compound is polyvinylpyrrolidone.

According to one embodiment of the present disclosure, the composite structure further comprises a metal nanoparticle adsorbed on the graphene layer.

According to one embodiment of the present disclosure, the metal nanoparticle is made of silver (Ag).

Further, the present disclosure also provides a method of manufacturing the composite structure of the transparent electrode. According to one embodiment of the present disclosure, the method comprises the steps of:

(1) depositing inhomogeneously a nanofiber substrate on a transparent substrate so as to form a light-permeable plane net structure;

(2) mixing the graphene oxide with an organic compound, and enabling the graphene oxide to be adsorbed to the organic compound to form a first mixture. The organic compound has at least a functional group selected from the group consisting phenyl, pyridyl, pyrimidinyl, carbazolyl, imidazolyl, pyrrolyl, pyrrolidinyl, pyrrolidone, hydroxyl, carbonyl, amine, secondary amine, tertiary amine, a fluorine atom, and a combination thereof;

(3) enabling the organic compound of the first mixture to be adsorbed, by a non-covalent interaction, on the surface of the nanofiber substrate, wherein the graphene oxide of the first mixture overlaps to each other; and

(4) reducing oxygen-containing groups of the graphene oxide to carbon-carbon double bond (C═C) in the presence of a reducing agent and heat, so as to form the composite for the transparent electrode.

According to one embodiment of the present disclosure, the step of depositing is employed by an electrochemical deposition, a chemical vapor deposition, a magnetron sputtering deposition, a screen printing deposition, a electrospinning deposition, a deposition method of the self-assembled chemical adsorption, a chemical etching, an optical etching, lithography, or a combination thereof.

According to one embodiment of the present disclosure, the non-covalent interaction is one selected from the group consisting of electrostatic interaction, hydrogen-bond interaction, π-π interaction and a combination thereof.

According to one embodiment of the present disclosure, the step (3) further comprises the following. A metal compound is added to the first mixture to form a second mixture bonded with the non-covalent interaction. Afterwards, the second mixture is adsorbed on the surface of the nanofiber substrate in the light-permeable plane net structure. Through a reduction reaction, the metal compound is reduced to be metal nanoparticles, and decrease the surface resistance of the transparent electrode significantly.

According to one embodiment of the present disclosure, the elevated temperature ranges from 100° C. to 350° C. As an embodiment, in the graphene oxide reduction step a reducing agent is applied to significantly reduce the desired temperature and to achieve the fully graphene reduction.

According to one embodiment of the present disclosure, the manufacturing method further comprises that the composite structure for the transparent electrode is arranged in an elevated temperature to fuse the nanofiber substrate of the composite structure, so as to form a transparent film.

### BRIEF DESCRIPTION OF THE DRAWINGS

FIG. 1A is a schematic diagram of the structure of the transparent electrode composite according to one embodiment of the present disclosure;

FIG. 1B is a schematic diagram of the meso-structure of the transparent electrode composite according to one embodiment of the present disclosure;

FIG. 1C is a schematic diagram of the structure of the transparent electrode composite structure according to one embodiment of the present disclosure;

FIG. 2A is a flow chart of a method for manufacturing the transparent electrode composite according to one embodiment of the present disclosure;

FIG. 2B is a high-resolution SEM image of the Nylon 66 substrate according to one embodiment of the present disclosure, wherein the time of electrospinning deposition is 120 s;

FIG. 2C is a high-resolution SEM image of the Nylon 66 substrate according to one embodiment of the present disclosure, wherein the time of electrospinning deposition is 180 s;

FIG. 2D is a high-resolution SEM image of the Nylon 66 substrate and graphene layer according to one embodiment of the present disclosure, wherein the arrow points out the surface of the Nylon 66 substrate without the graphene layer;

FIG. 2E is a high-resolution SEM image of the Nylon 66 substrate and the first mixture according to one embodiment of the present disclosure;

FIG. 2F is a high-resolution SEM image of the Nylon 66 substrate and the first mixture according to one embodiment of the present disclosure, wherein the graphene oxide has been reduced by hydrazine;

FIG. 2G is a high-resolution SEM image of the Nylon 66 substrate and the first mixture according to one embodiment of the present disclosure, wherein the graphene is treated by the heat reduction;

FIG. 3A is a flow chart of a method for manufacturing the second mixture according to one embodiment of the present disclosure;

FIG. 3B is a TEM image of the graphene oxide according to one embodiment of the present disclosure;

FIG. 3C is a TEM image of the graphene oxide according to one embodiment of the present disclosure, wherein the ratio of the Ag nanoparticles and the graphene in the second mixture is 1:1

FIG. 3D is a TEM image of the graphene oxide according to one embodiment of the present disclosure, wherein the ratio of the Ag nanoparticles and the graphene in the second mixture is 3:1;

FIG. 3E is a TEM image of the graphene oxide according to one embodiment of the present disclosure, wherein the ratio of the Ag nanoparticles and the graphene in the second mixture is 5:1;

FIG. 4 is a flow chart of the method of the heat treatment according to one embodiment of the present disclosure;

FIG. 5A is a plot of the surface resistance of the GNS/PA66, wherein the horizontal axis is the electrospinning time (sec.) and the vertical axis is the surface resistance (Ω/sq), and the graphene contents are 0.025 wt % (▪), 0.050 wt % (), 0.100 wt % (▴) and 0.200 wt % (★), respectively;

FIG. 5B is a plot of the transmittance of the GNS/PA66, wherein the horizontal axis is the electrospinning time (sec.) and the vertical axis is the light transmittance (%), the control is nanofiber substrate (▪), and the graphene contents are 0.025 wt % () and 0.200 wt % (★), respectively;

FIG. 5C is a image of the Nylon 66 substrate according to one embodiment of the present disclosure, wherein the electrospinning time of the image from right to left are 60 s, 90 s, 120 s, 150 s and 180 s, respectively;

FIG. 6A is a plot of the surface resistance of the PVP-GNS/PA66, wherein the horizontal axis is the electrospinning time (sec.) and the vertical axis is the surface resistance (Ω/sq), and the first mixture contents are 0.025 wt % (▪), 0.050 wt % (), 0.100 wt % (▴) and 0.200 wt % (★), respectively;

FIG. 6B is a plot of the transmittance of the PVP-GNS/PA66, wherein the horizontal axis is the electrospinning time (sec.) and the vertical axis is the light transmittance (%), the control is nanofiber substrate (▪), and the first mixture contents are 0.025 wt % () and 0.200 wt % (★), respectively;

FIG. 6C is a plot of the surface resistance and the transmittance of the PVP-GNS/PA66 before and after the heat treatment, wherein the horizontal axis is the electrospinning time (sec.), and the vertical axis on the left side is the surface resistance (Ω/sq), PVP-GNS/PA66 (▪) and A-PVP-GNS/PA66 (□). And the vertical axis on the right side is the transmittance (%), PVP-GNS/PA66 (▴) and A-PVP-GNS/PA66 (Δ);

FIG. 6D is an image of the composite material PVP-GNS/PA66 before and after the heat treatment according to one embodiment of the present disclosure, wherein the left side is before 350° C. of the heat treatment, and the right side is after 350° C. of the heat treatment;

FIG. 7A is a plot of the surface resistance of the PU composite material, wherein the horizontal axis is the electrospinning time (sec.) and the vertical axis is the surface resistance (Ω/sq), and AgNps (▪), GNS (), AgNps-GNS(1:1) (▴), AgNps-GNS(3:1) (♦) and AgNps-GNS(5:1) (★);

FIG. 7B is a plot of the transmittance of the PU composite material, wherein the horizontal axis is the electrospinning time (sec.) and the vertical axis is the light transmittance (%), the PU fiber substrate (▪), AgNps-GNS(1:1) (▴), AgNps-GNS(3:1) (♦) and AgNps-GNS(5:1) (★);

FIG. 7C is a plot of the surface resistance and the transmittance of the AgNps-GNS(5:1)/PU before and after the heat treatment, wherein the horizontal axis is the electrospinning time (sec.), and the vertical axis on the left side is the surface resistance (Ω/sq), AgNps-GNS(5:1)/PU (▪) and M-AgNps-GNS(5:1)/PU (□). And the vertical axis on the right side is the transmittance (%), AgNps-GNS(5:1)/PU (▪) and M-AgNps-GNS(5:1)/PU (Δ);

FIG. 7D is an image of the composite material the composite material of PU nanofiber before and after the heat treatment according to one embodiment of the present disclosure, wherein the left side is before 100° C. of the heat treatment, and the right side is after 100° C. of the heat treatment;

FIG. 7E is a plot of the surface resistance of the M-AgNps-GNS/PU, wherein the horizontal axis is the degree of the bending angle (°) and the vertical axis is the surface resistance (Ω/sq), and M-AGNPS-GNS(1:1)/PU (▴), M-AGNPS-GNS(3:1) (♦) and M-AgNps-GNS(5:1) (★).

### DETAILED DESCRIPTION

For better understanding the present disclosure, the following embodiments of the present disclosure are described. However, these examples are only as illustrative purposes of demonstration, and the scope and application of the present disclosure does not pose any restrictions. To the contrary, these embodiments will allow persons with ordinary skill in the art to know the present disclosure more thorough and complete, so as to fully express the scope of protection of the present disclosure. To clearly indicate the disclosure with the drawings, the shape and size may be exaggerated, in which the same reference numerals are used to designate the same or similar components.

Composite structures of the transparent electrode

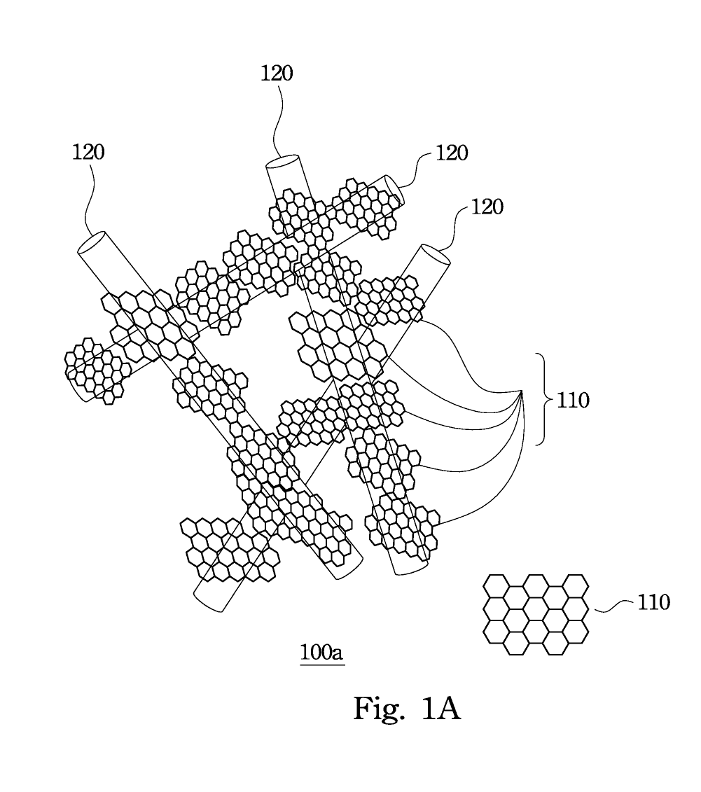

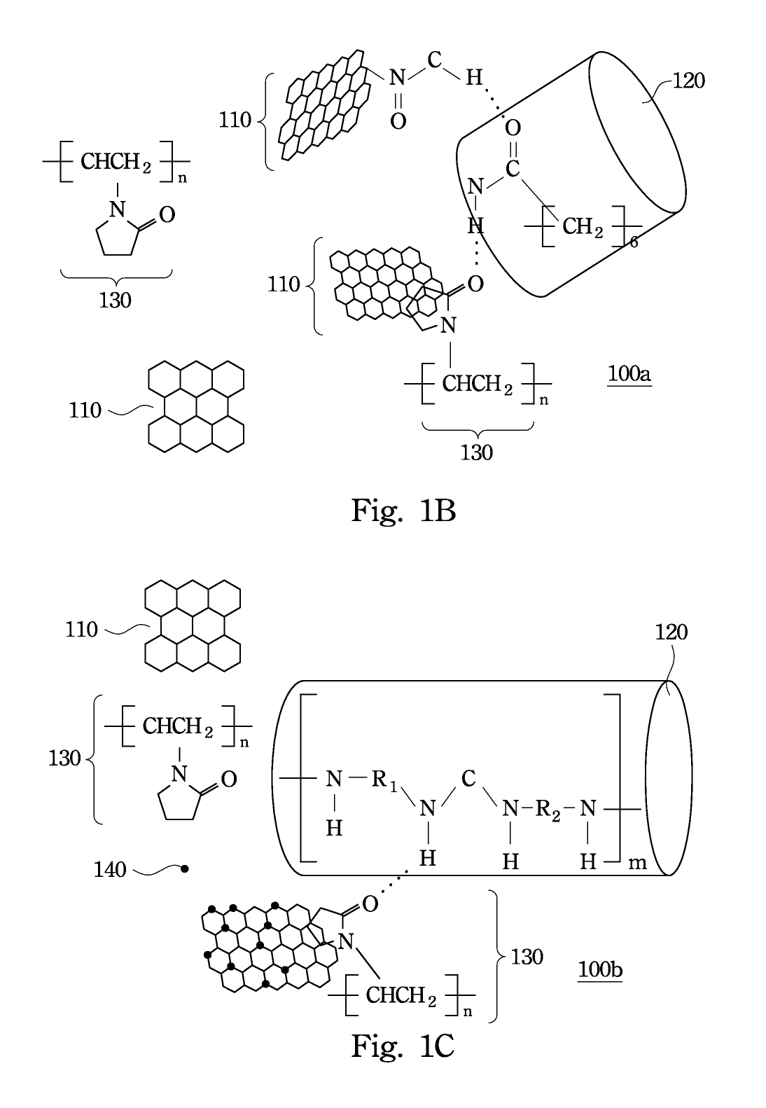

FIG. 1A is a schematic diagram of the structure of a transparent electrode 100a according to one embodiment of the present disclosure, and the FIG. 1B is a schematic diagram of the meso-structure of the transparent electrode 100a. In FIG. 1A, a graphene layer 110 is adsorbed on the surface of a nanofiber substrate 120 to form the transparent electrode 100a. The nanofiber substrate 120 has a plane net structure with light transmittance. The graphene layer 110 includes overlapped to each other in one or more layers of graphene. Since the graphene layer 110 has carboxylic acid group (COON), and the carboxylic acid group may generate hydrogen-bond interaction with the electron-withdrawing group of the nanofiber substrate 120. Thus, the graphene layer 110 is only located on the surface of the nanofiber substrate 120 and not distributed on the other position, and is formed a conductive network having the plane net structure with light transmittance.

According to one embodiment of the present disclosure, the nanofiber substrate 120 comprises Nylon 66, polyurethane or polystyrene. According to another embodiment of the present disclosure, the electron-withdrawing group of the nanofiber substrate 120 comprises carbonyl (C═O), primary amine, secondary amine, tertiary amine, fluorine atoms or a combination thereof.

The adsorption between the graphene layer 110 and the nanofiber substrate 120 (see FIG. 1B) shows that an organic compound 130 is positioned between the graphene layer 110 and the nanofiber substrate 120, and the organic compound 130 generates non-covalent interactions to the graphene layer 110 and the nanofiber substrate 120 respectively. The organic compound 130 has a group comprising phenyl, pyridyl, pyrimidinyl, carbazolyl, imidazolyl, pyrrolyl, pyrrolidinyl, pyrrolidinone, hydroxyl, carbonyl, primary amine, secondary amine, tertiary amine, a fluorine atom or a combination thereof. The graphene layer 110 has a plurality of conjugated π-electrons, and these π-electrons can generate π-π interaction with the electron-rich conjugated groups of the organic compound. Therefore, according to one embodiment of the present disclosure, a portion of the structure of the organic compound 130 has a electron-rich conjugated group (such as an aromatic ring or a heterocyclic ring), and another portion has electron-donating groups or electron-withdrawing groups (e.g. carbonyl, C═O), so it can respectively generate adsorption to the graphene layer 110 and the nanofiber substrate 120 in different directions of the organic compound. In this way, the organic compound 130 may assist in stabilizing the graphene layer 110 adsorbed on the nanofiber substrate 120 to avoid disconnection caused by the shedding of the graphene layer 110.

According to one embodiment of the present disclosure, the organic compound 130 is polyvinylpyrrolidone (PVP). Because the three-dimensional structure of the pyrrolidone group of polyvinylpyrrolidone having u electrons can be generated π-π interaction, and the pyrrolidone group having carbonyl (C═O) group can generate hydrogen-bonding interactions with the nanofiber.

FIG. 1C is a schematic diagram of the structure of the transparent electrode 100b according to another embodiment of the present disclosure. FIG. 1C is different with FIG. 1B, in FIG. 1C, a metal nanoparticles 140 is adsorbed on the graphene layer 110, and by the metal nano-particles 140 may reduce the surface resistance of the transparent electrode 100b. It is similar with the transparent electrode 100a in FIG. 1A, the transparent electrode 100b is also formed the conductive network having the plane net structure with light transmittance.

### Method for Manufacturing the Composite Structure of Transparent Electrode

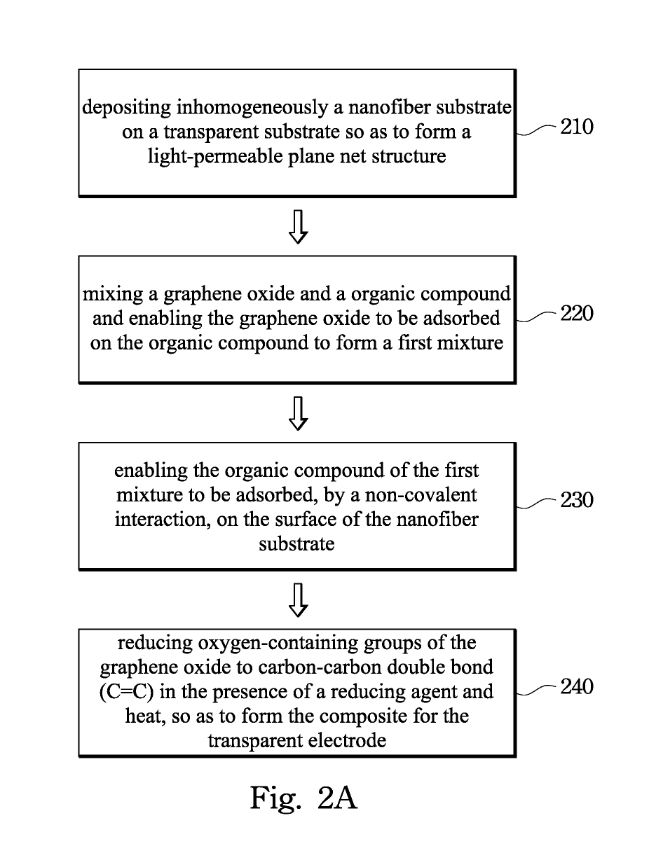

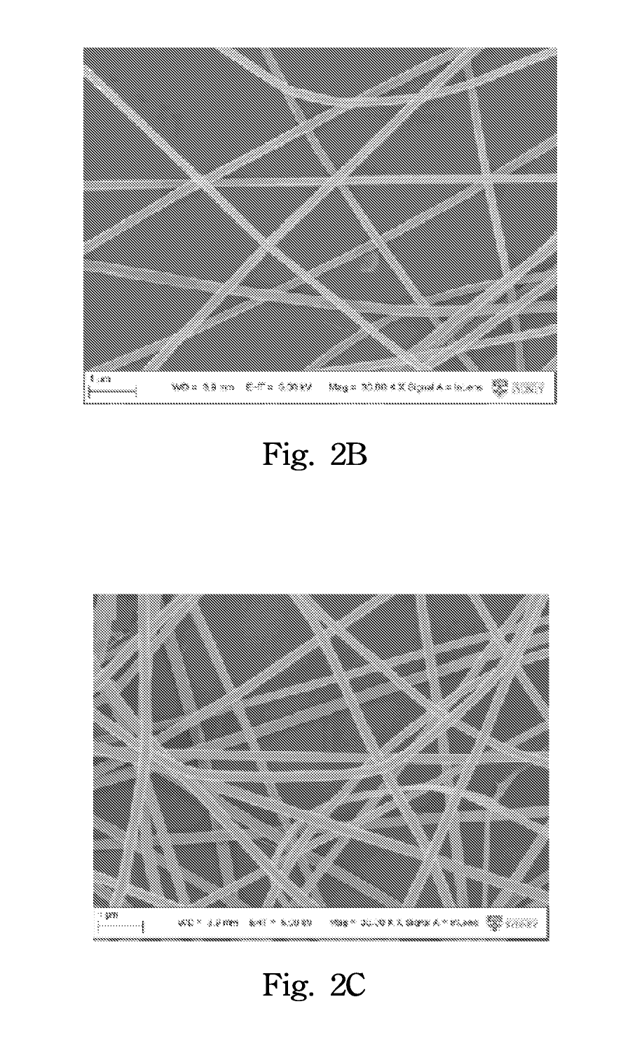

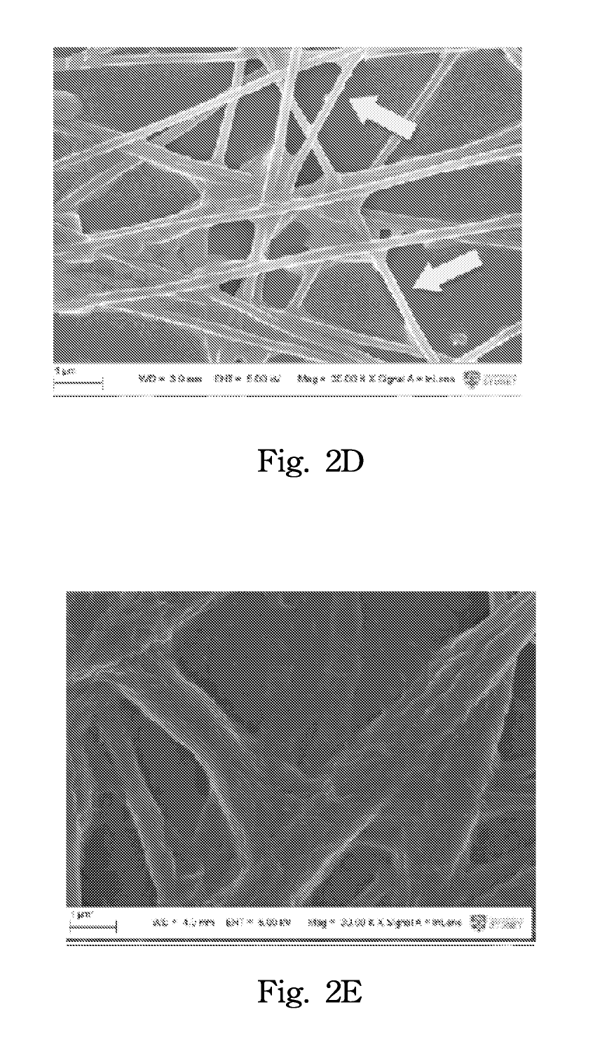

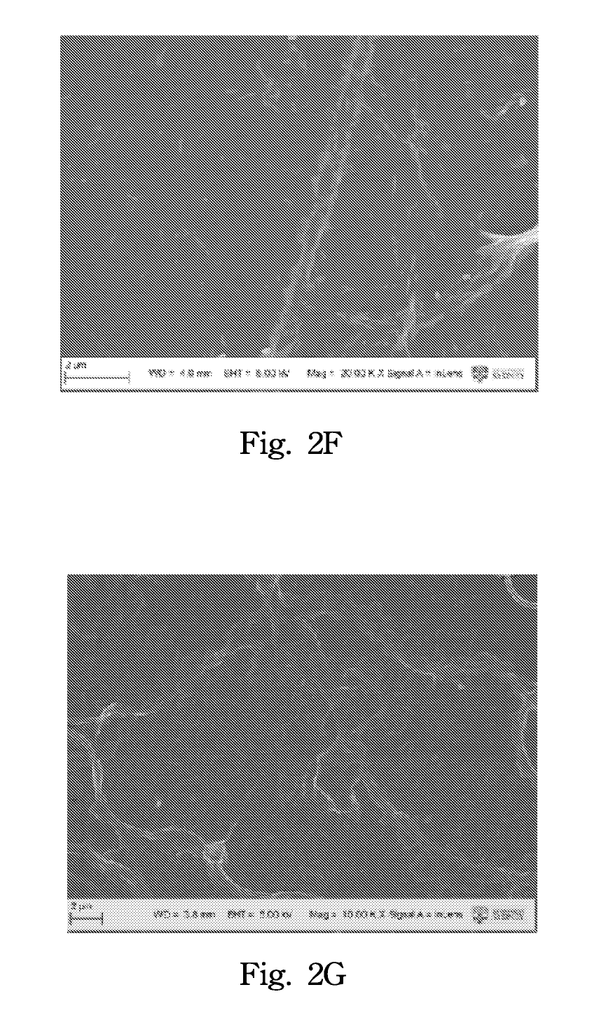

FIG. 2A is a flow chart of a method for manufacturing the transparent electrode composite according to one embodiment of the present disclosure.

In FIG. 2A, manufacturing a transparent electrode is needed sequentially depositing a nanofiber substrate (step 210), preparing a first mixture (step 220), the first mixture adsorbed on the nanofiber substrate (step 230), and reducing the graphene oxide (step 240).

In step 210 shown in FIG. 2A, it's depositing the nanofiber substrate non-uniformly on a transparent substrate, wherein the nanofiber substrate is rendered a plane net structure with light transmittance. As the deposition time longer, the density of the nanofiber substrate is the higher. On one hand, when the density of nanofiber substrate is too high, the holes between the nanofiber substrate may cause light scattering to show the milky white status. On the other hand, when the deposition time is too short to cause insufficient density of the nanofiber substrate and not reached the percolation value. When the conductive material reaches a percolation value, the resistance will drop dramatically and form conductive paths.

According to one embodiment of the present disclosure, the material of the nanofiber material is Nylon 66 or polyurethane.

According to one embodiment of the present disclosure, the deposition method comprises the electrochemical deposition, the chemical vapor deposition, the magnetron sputtering deposition, the screen printing deposition, the electrospinning deposition, the deposition of the self-assembled chemical adsorption, the chemical etching, the optical etching, lithography, or a combination thereof.

According to one embodiment of the present disclosure, if the electrospinning time is longer than 120 seconds (s), the density of nanofiber substrate is too high to show the milky white status.

FIG. 2B is a high-resolution SEM image of the Nylon 66 substrate according to one embodiment of the present disclosure, wherein the time of electrospinning deposition is 120 s. FIG. 2C is a high-resolution SEM image of the Nylon 66 substrate according to one embodiment of the present disclosure, wherein the time of electrospinning deposition is 180 s. Compared to FIG. 2B, the density of the Nylon 66 substrate in FIG. 2C is significantly higher.

In step 220 shown in FIG. 2A, a graphene oxide and an organic compound are mixed into a first mixture. By non-covalent interactions, the graphene oxide is adsorbed with organic compound.

According to one embodiment of the present disclosure, the graphene oxide is made by Hummers method. Using sodium nitrate (NaNO₃) activates graphene, and then oxidizes graphene by potassium permanganate (KMnO4). The carbon-carbon double bond (C═C) of the graphene is broken to form a plurality of oxygen-containing groups.

According to one embodiment of the present disclosure, the organic compound is polyvinylpyrrolidone (PVP). By π-π interaction, polyvinyl pyrrolidone (PVP) can be adsorbed with the graphene oxide.

In step 230 shown in FIG. 2A, the nanofiber substrate prepared by the step 210 is impregnated in the first mixture prepared by step 220, and the graphene oxide and the organic compound of the first mixture are adsorbed on the nanofiber substrate. Since the nanofiber substrate has a plane net structure with light transmittance, the one or more layers of graphene oxide adsorbed on the nanofiber substrate are stacked on top of each other to form a graphene layer.

FIG. 2D is a high-resolution SEM image of the Nylon 66 substrate and graphene layer according to one embodiment of the present disclosure, wherein there is no polyvinylpyrrolidone (PVP) inside. The arrow in FIG. 2D points out the surface of the Nylon 66 substrate without the graphene layer. In FIG. 2D, the electrospinning time of the Nylon 66 substrate is 120 s, and the concentration of the graphene oxide is 0.050 wt %.

FIG. 2E is a high-resolution SEM image of the Nylon 66 substrate and the first mixture according to one embodiment of the present disclosure. In FIG. 2E, the electrospinning deposition time of the Nylon 66 substrate is 120 s, and the concentration of the first mixture is 0.050 wt %. Because of the addition of polyvinylpyrrolidone (PVP), the surface of the Nylon 66 substrate in FIG. 2E is completely adsorbed with the graphene oxide to form the conductive network. The coverage degree of the graphene layer on the surface of the nanofiber substrate is higher, and the conductivity of the transparent electrode composite is also higher. Therefore, compared to FIG. 2D, FIG. 2E shows polyvinylpyrrolidone (PVP), which may enhance the coverage degree of the graphene layer on the surface of the nanofiber substrate, and reduce the surface resistance of the composite material.

In step 240 shown in FIG. 2A, by using the reducing agent and the heat-reduction reaction, the graphene oxide is reduced to be graphene, and decrease the surface resistance of the graphene. Using a reducing agent alone may not be able to fully reduce the graphene oxide to graphene, such that oxide oxygen-containing group can not be reduced to the carbon-carbon double bond (C═C). And if using the heat reduction (i.e., reduction taken placed at an elevated temperature) alone, it is possible to destroy the material structure with the lower heat resistance. Therefore, in step 240, the use of a reducing agent and heat reduction reaction increases the reduction degree of graphene. By this method, it can decrease the using amount of the reducing agent, and decrease the temperature of the thermal reduction, in order to avoid the destruction of the material structure with lower heat resistance.

According to one embodiment of the present disclosure, the reducing agent is hydrazine (N₂H₄). According to another embodiment of the present disclosure, the temperature of the heat reduction is not higher than 350° C.

FIG. 2F is a high-resolution SEM image of the Nylon 66 substrate and the first mixture according to one embodiment of the present disclosure. In FIG. 2F, the graphene oxide is reduced by hydrazine.

FIG. 2G is a high-resolution SEM image of the Nylon 66 substrate and the first mixture according to one embodiment of the present disclosure. In FIG. 2G, the graphene is treated by the heat reduction. It is worth noting that, after the nanofiber substrate is melted, the graphene still has a mesh-like structure.

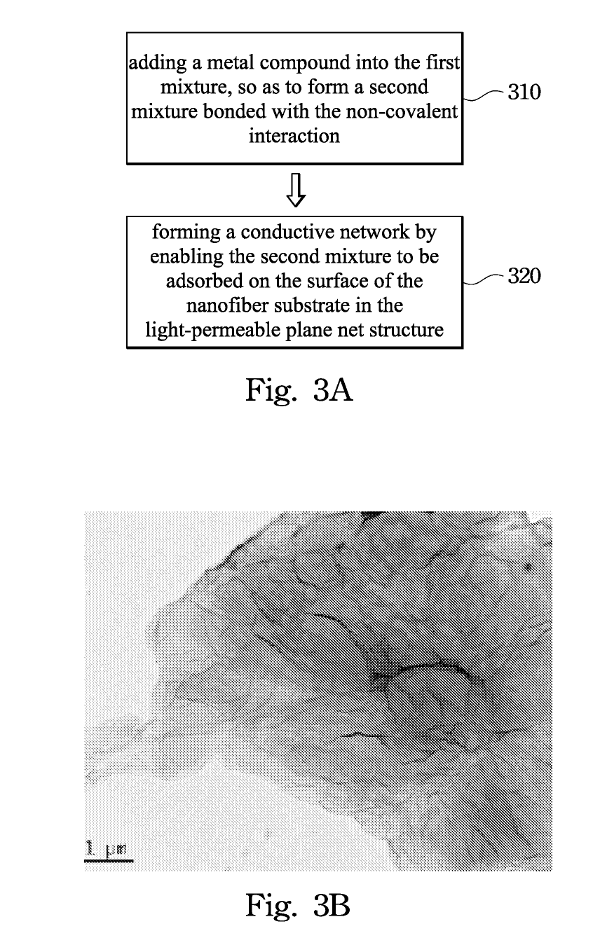

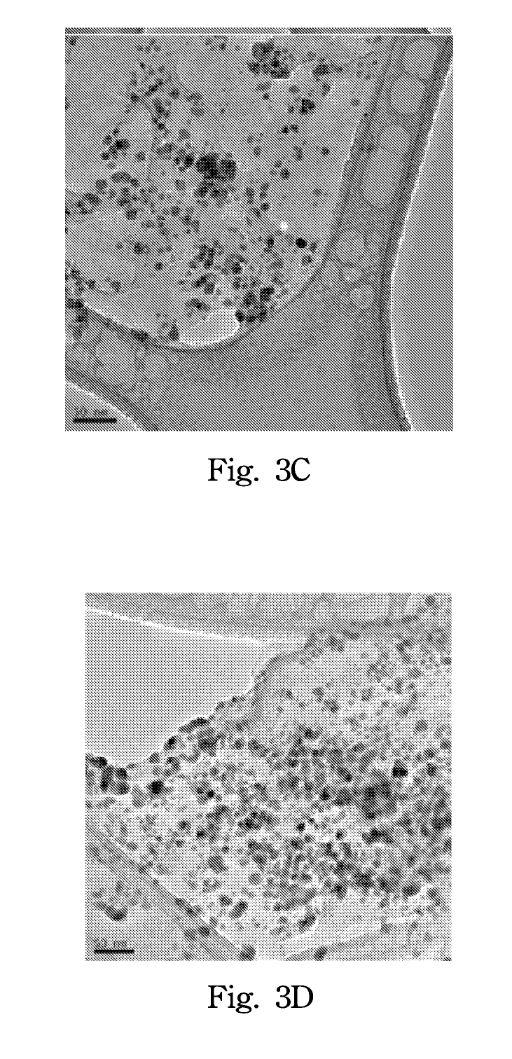

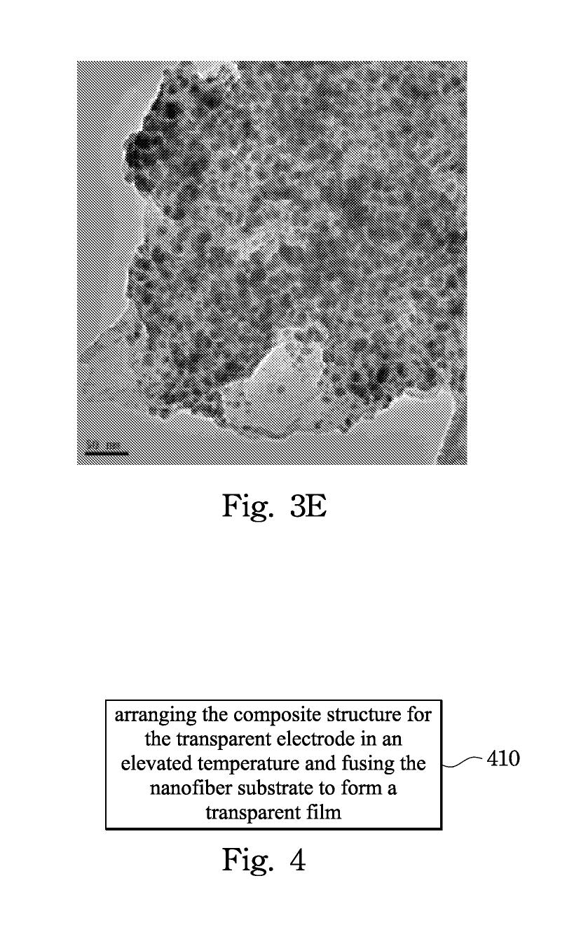

FIG. 3A is a flow chart of a method for manufacturing the second mixture according to one embodiment of the present disclosure.

In step 310 shown in FIG. 3A, a metal compound is added into the first mixture in step 220 of FIG. 2A, to form a second mixture. The metal ion of the metal compound generates electrostatic interaction with the oxygen-containing groups of the graphene oxide, and the metal ion is gathered at the graphene oxide surface with a negatively charge. According to one embodiment of the present disclosure, the metal compound is silver nitrate (AgNO₃).

In section 3A shown in step 320, the graphene oxide and the organic compound of the second mixture prepared by step 310 are adsorbed on the nanofiber substrate. Since the nanofiber substrate has the plane net structure with light transmittance, the graphene oxide adsorbed thereon are stacked on top of each other to form a graphene layer and a conductive path having the plane net structure with light transmittance.

After step 320, the reduction reaction in the step 240 of FIG. 2A is following. The metal ion and the graphene oxide are reduced to form AgNps-GNS. AgNps-GNS possesses conductivity and does not need to chemical reduction after adsorption. With the increase in the proportion of the metal nanoparticles and the graphene, the metal nanoparticles will accumulate on the graphene to form a flat and smooth surface. According to one embodiment of the present disclosure, the metal nanoparticles are silver nanoparticles (Ag-Nps). According to another embodiment of the present disclosure, the particle size of the silver nanoparticles is about 13 nm.

FIG. 3B is a TEM image of the graphene oxide according to one embodiment of the present disclosure. In FIG. 3B, the composite material of the transparent electrode is wrinkled to illustrate the composite material is flexible.

FIG. 3C is a TEM image of the graphene oxide according to one embodiment of the present disclosure. In FIG. 3C, the ratio of the Ag nanoparticles to the graphene in the second mixture is 1:1. It is worth noting that the silver nanoparticles are only gathered on the surface of the graphene, not dispersed in the other regions.

FIG. 3D is a TEM image of the graphene oxide according to one embodiment of the present disclosure. In FIG. 3D, the ratio of the Ag nanoparticles to the graphene in the second mixture is 3:1. It is worth noting that the silver nanoparticles are only gathered on the surface of the graphene, not dispersed in the other regions.

FIG. 3E is a TEM image of the graphene oxide according to one embodiment of the present disclosure. In FIG. 3E, the ratio of the Ag nanoparticles to the graphene in the second mixture is 5:1. It is worth noting that the silver nanoparticles are only gathered on the surface of the graphene, not dispersed in the other regions.

FIG. 3C-3E show that, by increasing the ratio of silver nanoparticles to the graphene, the silver nanoparticles may increase the coverage ratio of the graphene.

FIG. 4 is a flow chart of the method of the heat treatment according to one embodiment of the present disclosure.

In the step 410 shown in FIG. 4, the composite material prepared by the step 240 in FIG. 2A is heat-treated in a heating condition, and the nanofiber substrate of the composite material is melted to form a transparent film. The nanofiber substrate melted via heat treatment can enhance the transmittance of the composite material effectively. It is worth noting that, due to the transparent substrate in FIG. 4 is a flexible polymer material, the heat treatment temperature needs to be higher than the melting point of the nanofiber substrate (100° C.), and lower than the melting point of the transparent substrate (approximately 200° C.). According to one embodiment of the present disclosure, the heat treatment temperature is 100° C. to 350° C.

### Preparation of the Composite Structure Used in the Transparent Electrode and Measurement of the Surface Resistance and Light Transmittance

Using the manufacturing method mentioned above, it is firstly preparing the nanofiber substrate with different electrospinning time. The electrospinning time is 60 s, 90, 120 s, 150 s and 180 s, respectively. Then, the graphene oxide is prepared with different concentrations of the graphene oxide are 0.025 wt %, 0.050 wt %, 0.100 wt % and 0.200 wt %. The nanofiber substrates with different electrospinning time are immersed in the dispersion solutions of the graphene oxide with different concentrations for 10 min.

The graphene oxide is reduced by 0.1 wt % of hydrazine (N₂H₄), and then placed in the condition of 350° C. and followed the heat reduction for 30 min, to form the composite materials (GNS/PA66) with different contents of the graphene.

Comparing the surface resistance and light transmittance of the composite materials (GNS/PA66) with different contents of the graphene and different electrospinning time, and the results are shown as following.

TABLE 1A
measuring the surface resistance of GNS/PA66

| Surface Resistance of | | | | |
|---|---|---|---|---|
| GNS/PA66 (Ω/□) | Graphene Content | | | |
| Electrospinning Time | 0.025 | 0.050 | 0.100 | 0.200 |
| (sec) | wt % | wt % | wt % | wt % |
| 60 | 3.42 × 10⁹ | 8.73 × 10⁸ | 6.24 × 10⁸ | 3.51 × 10⁸ |
| 90 | 6.82 × 10⁸ | 3.11 × 10⁸ | 5.77 × 10⁷ | 2.07 × 10⁷ |
| 120 | 4.39 × 10⁸ | 7.02 × 10⁷ | 3.27 × 10⁶ | 3.82 × 10⁶ |
| 150 | 2.87 × 10⁸ | 8.29 × 10⁶ | 2.55 × 10⁶ | 1.32 × 10⁶ |
| 180 | 6.04 × 10⁷ | 5.49 × 10⁶ | 8.66 × 10⁵ | 8.43 × 10⁵ |

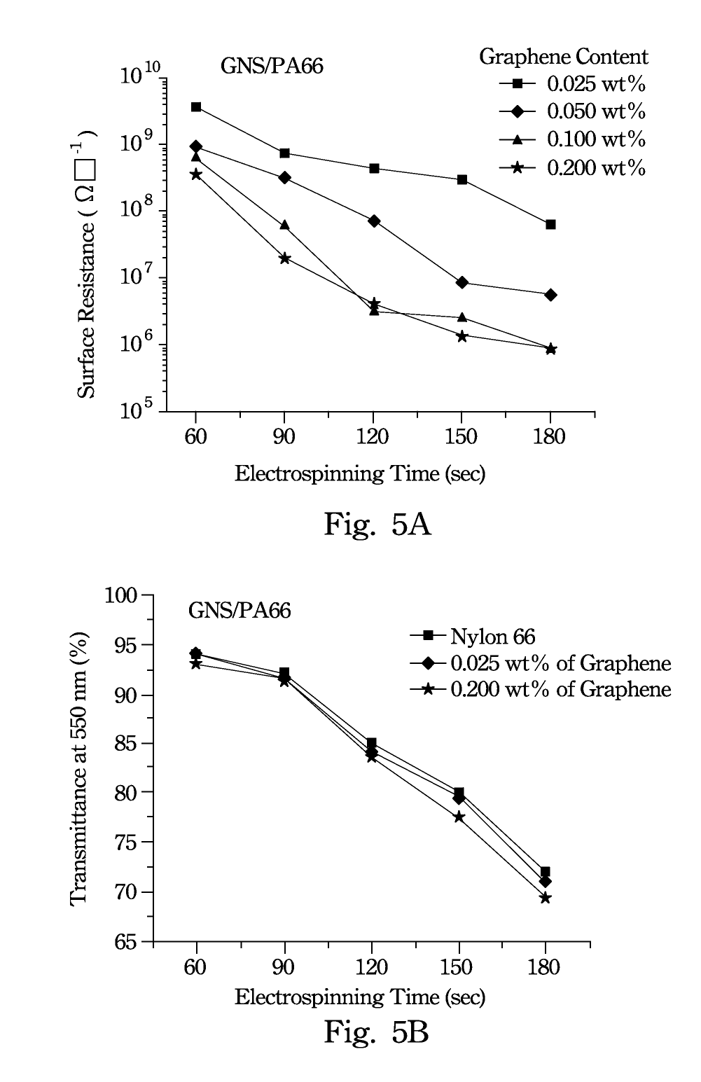

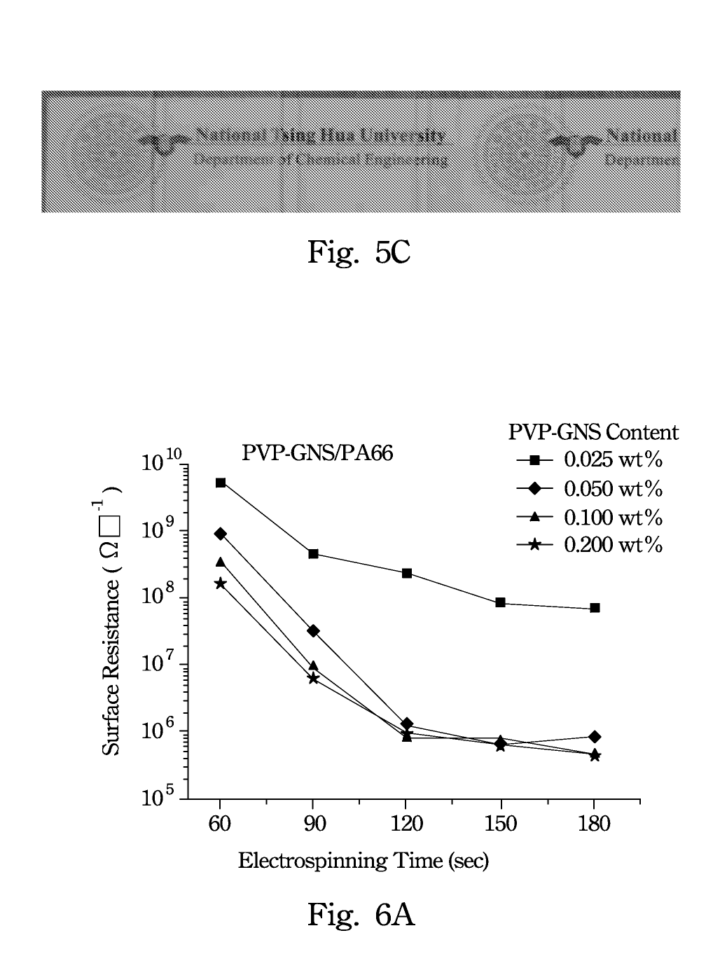

The results of Table 1A and FIG. 5A are shown that, with increasing the deposition time of electrospinning, the surface resistance of the composite material will be reduced. For example, the graphene amount of the composite material is 0.100 wt %; when the electrospinning time is 120 seconds, the surface resistance of the composite material is drastically decreased. In this case, the density of the Nylon 66 fiber is up to the percolation value. The Nylon 66 substrate reached percolation value has been formed a complete plane net structure with light transmittance, so that the graphene adsorbed thereon can be stacked to form a conductive network having the plane net structure with light transmittance.

Further, the results of Table 1A and FIG. 5A are also shown that, with increasing the graphene content, the surface resistance of the composite material will be reduced. For example, the electrospinning time of the composites is 120 seconds; when the graphene contents are 0.100 wt % to 0.200 wt %, the surface resistances of the composite materials do not decrease significantly. Because when the graphene contents are 0.100 wt % to 0.200 wt %, the graphene adsorbed on the Nylon 66 substrate has been saturated, and the surface resistance of the composite material does not decrease further more. It is worth noting that, when the electrospinning time is 120 seconds, the light transmittance of the composite material with the graphene content of 0.100 wt % is decreased significantly, and the equilibrium value of the photoelectric property is preferred.

TABLE 1B
Measuring the light transmittance of GNS/PA66

| Light Transmittance^{a} of | Graphene Content | | | | |
|---|---|---|---|---|---|
| GNS/PA66 (%) | | 0.025 | 0.050 | 0.100 | 0.200 |
| Electrospinning Time (sec) | Nylon 66 | wt % | wt % | wt % | wt % |
| 60 | 94 | 94 | 93.5 | 93 | 93 |
| 90 | 92 | 91.5 | 91.5 | 91.5 | 91.5 |
| 120 | 85 | 84 | 84 | 83.5 | 83.5 |
| 150 | 80 | 79.5 | 78.5 | 78 | 77.5 |
| 180 | 72 | 71 | 70.5 | 70 | 69.5 |

^{a}light transmittance: 550 nm of wave-length.

The results of Table 1B and FIG. 5B are shown that, with increasing the deposition time of the electrospinning, the light transmittance of the composite material will be reduced. When the electrospinning time of the Nylon 66 substrate is 180 seconds, the light transmittance is 72%. The electrospinning is longer, and the density of the Nylon 66 fiber substrate is higher to form a dense net structure. When the pore size of the nanofiber is similar to the wavelength of visible light, it may cause light scattering decreasing the light transmittance.

Further, it is worth noting that, no matter how long the electrospinning time of the composite material is, increasing the graphene content does not affect the light transmittance of the composite material. Since the graphene layer is adsorbed on the nanofiber substrate and formed a flaky structure, the impact of light transmittance of composite material is minimum. Therefore, the light scattering of the composite material is the most important factor affecting the light transmittance of the composite material.

FIG. 5C is an image of the Nylon 66 substrate according to one embodiment of the present disclosure. In FIG. 5C, the electrospinning time of the Nylon 66 substrate is longer, and then the milky white status of the surface is more significant.

### Preparation of the Composite Structure PVP-GNS/PA66 Used in the Transparent Electrode and Measuring the Surface Resistance and Light Transmittance Thereof and the Heat Treatment Thereof

Using the manufacturing method mentioned above, it is firstly preparing the nanofiber substrate with different electrospinning time. The electrospinning time is 60 s, 90, 120 s, 150 s and 180 s, respectively. Then, the weight proportion of the graphene oxide (GO) and polyvinylpyrrolidone (PVP) is 1:4 to prepare a first mixture. The first mixture is prepared to a dispersion solution of the first mixture, and the concentrations of which are 0.025 wt %, 0.050 wt %, 0.100 wt % and 0.200 wt %. The nanofiber substrates with different electrospinning time are immersed in the dispersion solutions of the first mixture with different concentrations for 10 min.

The first mixture is reduced by 0.1 wt % of hydrazine (N₂H₄), and then placed in the condition of 350° C. and followed the heat reduction for 30 min, to form the composite materials (PVP-GNS/PA66) with different contents of the graphene and polyvinylpyrrolidone (PVP-GNS).

Comparing the surface resistance and the light transmittance of the composite materials (PVP-GNS/PA66) with different contents of the first mixture and different electrospinning time, and the results are shown as following.

TABLE 2A
measuring the surface resistance of PVP-GNS/PA66

| Surface Resistance of | | | | |
|---|---|---|---|---|
| PVP-GNS/PA66 (Ω/□) | PVP-GNS^{a} Content | | | |
| Electrospinning Time | 0.025 | 0.050 | 0.100 | 0.200 |
| (sec) | wt % | wt % | wt % | wt % |
| 60 | 5.52 × 10⁹ | 8.23 × 10⁸ | 3.27 × 10⁸ | 1.57 × 10⁸ |
| 90 | 4.54 × 10⁸ | 3.31 × 10⁷ | 8.37 × 10⁶ | 7.37 × 10⁶ |
| 120 | 2.76 × 10⁸ | 1.37 × 10⁶ | 8.47 × 10⁵ | 8.62 × 10⁵ |
| 150 | 8.66 × 10⁷ | 6.59 × 10⁵ | 7.58 × 10⁵ | 6.37 × 10⁵ |
| 180 | 7.14 × 10⁷ | 8.43 × 10⁵ | 4.36 × 10⁵ | 4.45 × 10⁵ |

^{a}PVP-GNS is mixed by graphene (GNS) and polyvinylpyrrolidone (PVP).

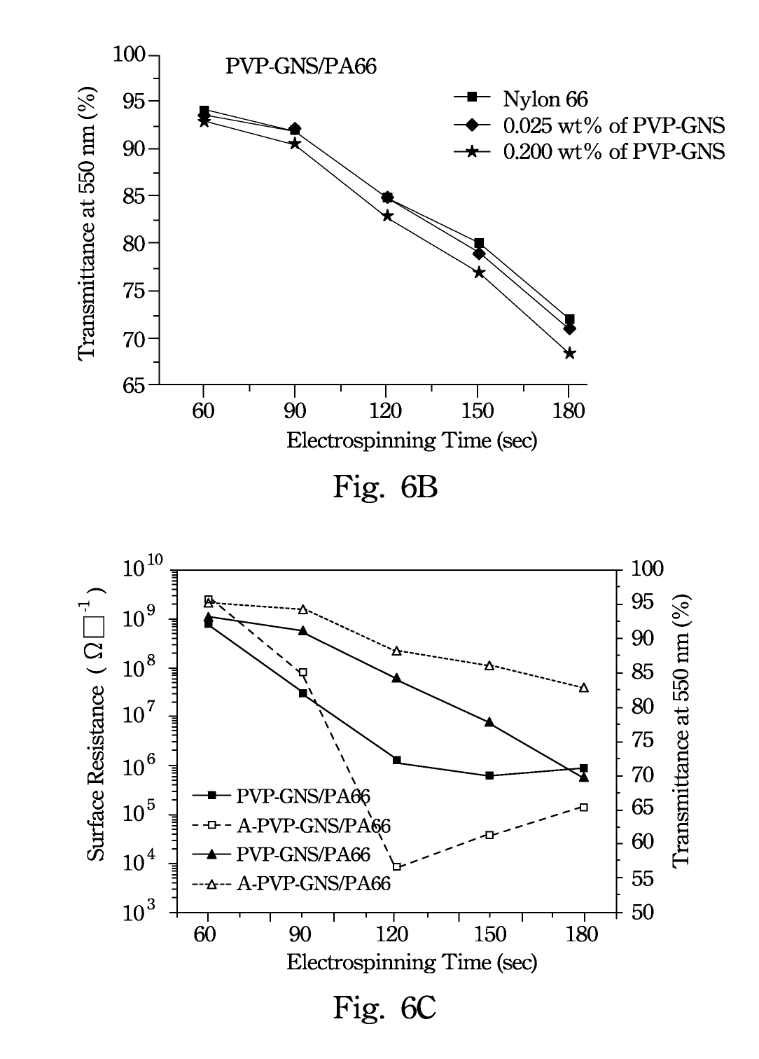

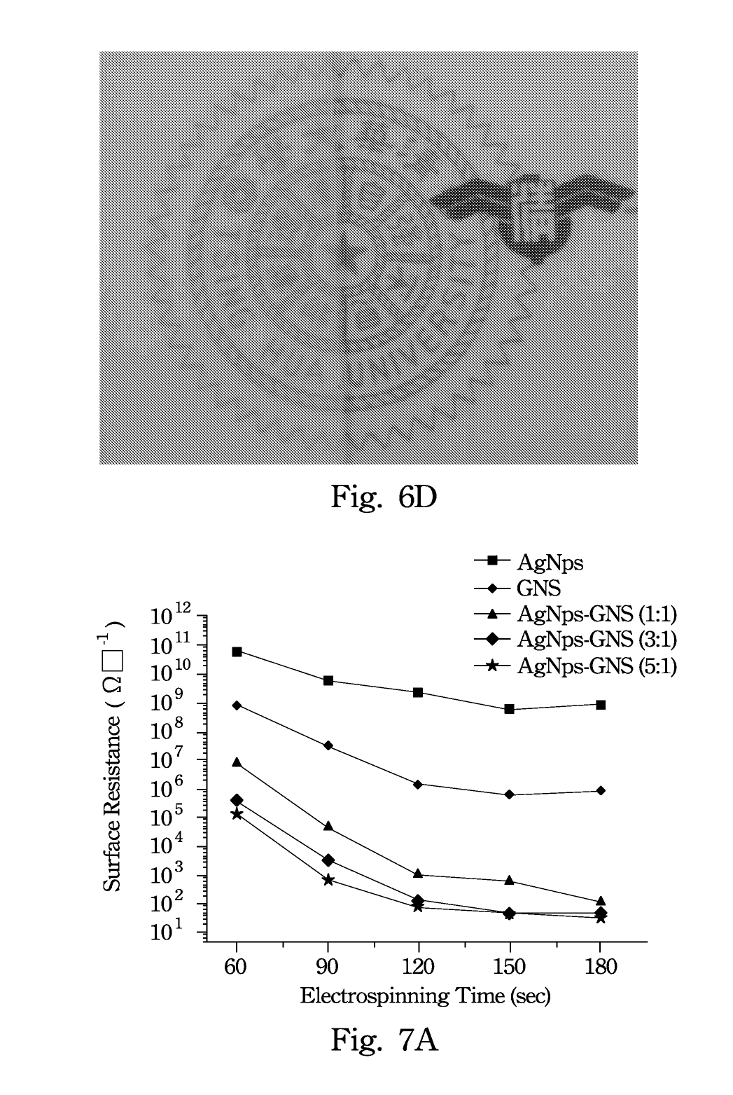

The results of Table 2A and FIG. 6A are shown that, when the electrospinning time of the composite materials is 180 seconds and the PVP-GNS content is 0.200 wt %, the composite material may have the lowest surface resistance of 4.43×10⁵ Ω/□. However, when the PVP-GNS content is 0.050 wt %, the surface resistance is decreased and saturated. Compared to the results of Table 1A, in Table 2A, the composite materials with polyvinylpyrrolidone used the lower content of graphene have lower surface resistances. For example, in Table 1A, when the electrospinning time is 120 seconds and the graphene content is 0.050 wt %, the surface resistance of the composite material is 7.02×10⁷ Ω/□. In Table 2A, the surface resistance of the composite material is 1.37×10⁶ Ω/□. The results indicate that, polyvinylpyrrolidone (PVP) helps graphene adsorbed on the surface of the nanofiber to form a more complete conductive network.

According to the charge percolation theory, when a conductive substance presented on a complex material or film surface reaches a percolation threshold value, it will form the interconnected conductive paths. This interconnected conductive path may increase rapidly the conductivity of the composite film. Compare the results in Table 2A and Table 1A, polyvinylpyrrolidone (PVP) may increase the percolation threshold value of graphene, reduce the using amount of the PVP-GNS, and form a conductive network having the plane net structure with light transmittance.

TABLE 2B
Measuring the light transmittance of PVP-GNS/PA66

| Light Transmittance^{a} of | PVP-GNS content (%) | | | | |
|---|---|---|---|---|---|
| PVP-GNS/PA66 (%) | | 0.025 | 0.050 | 0.100 | 0.200 |
| Electrospinning Time (sec) | Nylon 66 | wt % | wt % | wt % | wt % |
| 60 | 94 | 93.5 | 93 | 93 | 93 |
| 90 | 92 | 92 | 91 | 91 | 90.5 |
| 120 | 85 | 85 | 84 | 83.5 | 83 |
| 150 | 80 | 79 | 77.5 | 77.5 | 77 |
| 180 | 72 | 71 | 70.5 | 69.5 | 68.5 |

^{a}light transmittance: 550 nm of wavelength.

The results of Table 2B and FIG. 6B are shown that, with increasing the deposition time of the electrospinning, the light transmittance of the composite material will be reduced. But no matter how long the electrospinning time of the composite material is, the increment in the graphene content does not affect the light transmittance of the composite material. Therefore, the light scattering of the composite material is the most important factor affecting the light transmittance of the composite material. The result is the same as the results of Table 1B and FIG. 5B.

TABLE 2C
Heat Treatment^{a} of PVP-GNS/PA66

| PVP-GNS/PA66 | | | | |
|---|---|---|---|---|
| content is | Surface Resistance | | | |
| 0.050 wt % | (Ω/□) | | Light Transmittance (%) | |
| Electrospinning | Before Heat | After Heat | Before Heat | After Heat |
| Time (sec) | Treating | Treating | Treating | Treating |
| 60 | 8.23 × 10⁸ | 2.49 × 10⁹ | 93 | 95 |
| 90 | 3.31 × 10⁷ | 8.01 × 10⁷ | 91 | 94 |
| 120 | 1.37 × 10⁶ | 8.61 × 10³ | 84 | 88 |
| 150 | 6.59 × 10⁵ | 3.85 × 10⁴ | 77.5 | 86 |
| 180 | 8.43 × 10⁵ | 1.31 × 10⁵ | 70.5 | 82.5 |

^{a}PVP-GNS/PA66 is heat-treated at 350° C.

Table 2C and FIG. 6C are shown the difference of the surface resistance and the light transmittance of the PVP-GNS/PA66 composite before and after heat treatment at 350° C., wherein the PVP-GNS content of the composite is 0.050 wt %. The results of Table 2C and FIG. 6C are also shown that, when the electrospinning time of the composite material is less than 120 seconds, the fiber density of the Nylon 66 substrate is less, so that the stacked structure of graphene will be destroyed by the heat treatment of 350° C., resulting in increased the surface resistance. Conversely, when the electrospinning time of the composites is 120 seconds or more, the fiber density of the Nylon 66 substrate is sufficient to stand the melting of the fibers without affecting the net structure of the graphene, and to decrease the surface resistance of the composite materials.

In addition, Table 2C and FIG. 6C are shown that, the composite material PVP-GNS/PA66 is significantly increased by the heat treatment of 350° C. Since the heat treatment will destroy the structure of the nanofiber substrate to form a uniform film, the light scattering is also disappeared. The electrospinning time is longer, and then the transmittance after heat treatment is increased significantly. For example, when the electrospinning time of the composite material is 60 seconds, the light transmittance before the heat treatment is 93%, and the transmittance after the heat treatment is 95%. The electrospinning time is 180 seconds, the light transmittance before the heat treatment is 70.5%, and the transmittance after the heat treatment is 82.5%.

FIG. 6D is an image of the composite material PVP-GNS/PA66 before and after the heat treatment according to one embodiment of the present disclosure. In FIG. 6D, the electrospinning time of the composite material is 180 seconds, and the surface of which is milky white before the heat treatment and the surface of which is more transparent significantly after the heat treatment of 350° C.

### Preparation of the Composite Structure AgNps-GNS/PA66 Used in the Transparent Electrode and Measuring the Surface Resistance, Light Transmittance and Flexibility Thereof and the Heat Treatment Thereof

Using the manufacturing method mentioned above, it is firstly preparing the nanofiber substrate with different electrospinning time. The electrospinning time is 60 s, 90, 120 s, 150 s and 180 s, respectively. Then, the weight proportions of the graphene oxide (GO) and silver nanoparticles (AgNps) are 1:1, 1:3 and 1:5 to prepare three sets of AgNps-GO suspension solution with different content of AgNps, the concentrations of all are 0.05 wt %. Further a graphene oxide suspension solution is prepared without AgNps, and the concentration of which is 0.05 wt %. And an AgNps suspension solution is prepared without graphene oxide, and the concentration of which is 0.5 wt %. Wherein the graphene oxide suspension solution and the AgNps-GO suspension solution contain polyvinylpyrrolidone (PVP), and the weight ratio of PVP and GO is 1:4. Then, sodium borohydride (NaBH₄) is used to reduce graphene oxide of the AgNps-GO to form a dispersion solution having different contents of silver nanoparticles and graphene (AgNps-GNS).

The nanofiber substrates with different electrospinning time are immersed in the dispersion solutions of AgNps, GNS and Ag-GNS with different concentrations for 10 min. Comparing the surface resistance and the light transmittance of the composite materials AgNps-GNS/PU with different contents of AgNps, GNS, AgNps-GNS and different electrospinning time, and the results are shown as following.

TABLE 3A
Surface Resistance of Composite materials

| | Surface Resistance (Ω/□) | | | | |
|---|---|---|---|---|---|
| | | | AgNps- | AgNps- | AgNps- |
| Electro- | | | GNS | GNS | GNS |
| spinning | | | (1:1)/ | (3:1)/ | (5:1)/ |
| Time (sec) | AgNps/PU | GNS/PU | PU | PU | PU |
| 60 | 6.42 × 10¹⁰ | 8.65 × 10⁸ | 8.43 × 10⁶ | 4.24 × 10⁵ | 1.51 × 10⁵ |
| 90 | 6.21 × 10⁹ | 3.36 × 10⁷ | 5.11 × 10⁴ | 3.22 × 10³ | 7.07 × 10² |
| 120 | 2.36 × 10⁹ | 1.39 × 10⁶ | 1.13 × 10³ | 1.20 × 10² | 80 |
| 150 | 5.64 × 10⁸ | 6.48 × 10⁵ | 6.23 × 10² | 48 | 46 |
| 180 | 8.24 × 10⁸ | 8.72 × 10⁵ | 1.21 × 10² | 50 | 35 |

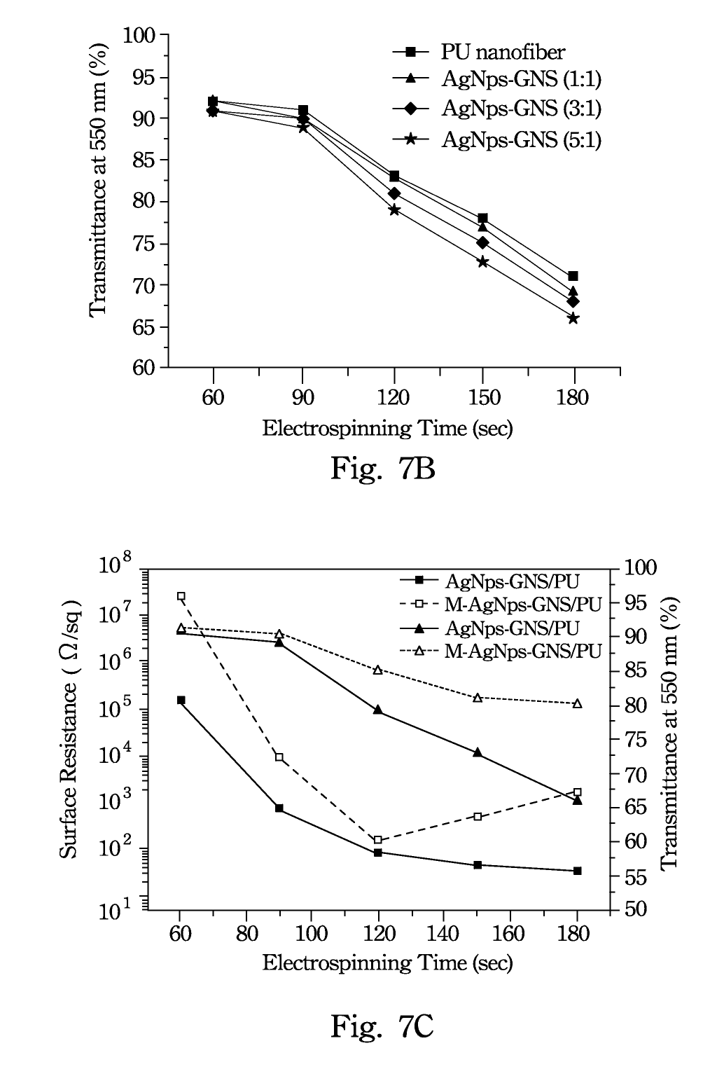

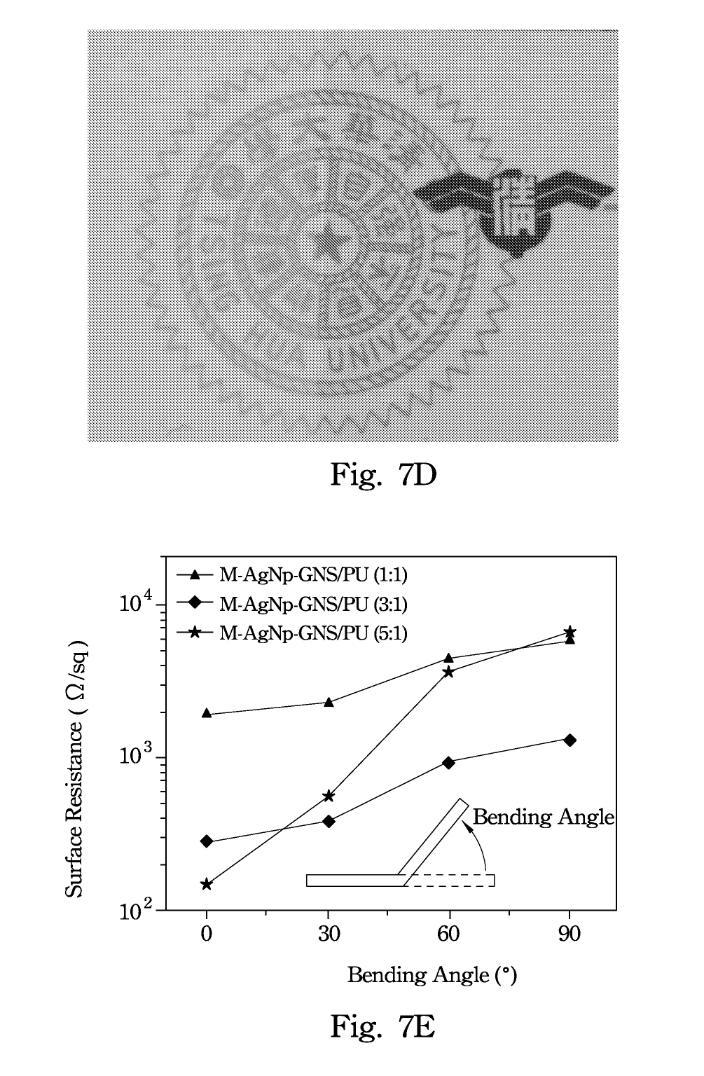

The results of Table 3A and FIG. 7A are shown that the surface resistance of AgNps/PU is higher than other sets. The silver nanoparticles are not adsorbed on the PU fiber substrate, and can not be aggregated to form a conductive path. Contrary, due to the graphene can adsorb on the nanofiber substrate, and overlap to form a conductive network.

On the other hand, when the electrospinning time is longer than 120 seconds, the surface resistance of the GNS/PU does not decrease significantly. Since the deposition density of the PU fiber substrate is gradually saturated, the graphene (GNS) cannot effectively reduce the surface resistance of the composite material GNS/PU. Compared to the surface resistance of the GNS/PU, when the electrospinning time is longer than 120 seconds, the surface resistance of AgNps-GNS/PU is also decreased significantly. According to one embodiment of the present disclosure, when the electrospinning time is 120 seconds, the surface resistance of the composite material AGNPS-GNS (5:1)/PU is 80 Ω/□. Because the electrospinning time of the nanofiber substrate is reached to 120 seconds or more, the density of the nanofiber is approaching percolation value. The proportion of silver nanoparticles (AgNps) and graphene (GNS) has also become an important factor affecting the surface resistance of the composite material.

When the proportion of the silver nanoparticles (AgNps) and graphene (GNS) is higher, the surface resistance of the composite material is lower. Because the aggregation of the silver nanoparticles forms a dense and efficient metal conductive path, it can reduce significantly the surface resistance of the composite material. According to one embodiment of the present disclosure, when the electrospinning time is 180 seconds, AgNps-GNS/PU (5:1) has the lowest surface resistance value of 35 Ω/□.

TABLE 3B
Light Transmittance of Composite Materials

| | Light Transmittance (%) | | | | |
|---|---|---|---|---|---|
| | | | | | AgNps- |
| Electrospinning | | | AgNps-GNS | AgNps-GNS | GNS |
| Time (sec) | AgNps | GNS | (1:1) | (3:1) | (5:1) |
| 60 | 94 | 93 | 92 | 91 | 91 |
| 90 | 91.5 | 91 | 90 | 90 | 89 |
| 120 | 84.5 | 84 | 83 | 81 | 79 |
| 150 | 79 | 77.5 | 77 | 75 | 73 |
| 180 | 71.5 | 70.5 | 69 | 68 | 66 |

The results of Table 3B and FIG. 7B are shown that, with increasing the deposition time of the electrospinning, the light transmittance of the composite material may be reduced. But no matter how long the electrospinning time of the composite material is, increasing the silver nanoparticles (AgNps) content does not affect the light transmittance of the composite material. Therefore, the light scattering of the composite material is the most important factor affecting the light transmittance of the composite material. The result is the same as the results of Table 1B and FIG. 5B.

TABLE 3C
Heat Treatment of AgNps-GNS (5:1)/PU

| AgNps-GNS | Surface Resistance | | Light Transmittance | |
|---|---|---|---|---|
| (5:1)/PU | (Ω/□) | | (%) | |
| Electrospinning | Before Heat | After Heat | Before Heat | After Heat |
| Time (sec) | Treating | Treating | Treating | Treating |
| 60 | 1.51 × 10⁵ | 2.54 × 10⁷ | 91 | 91 |
| 90 | 7.07 × 10² | 8.86 × 10³ | 89 | 90 |
| 120 | 80 | 1.50 × 10² | 79 | 85 |
| 150 | 46 | 4.80 × 10² | 73 | 81 |
| 180 | 35 | 1.65 × 10³ | 66 | 80 |

^{a}AgNps-GNS (5:1)/PU is heat treated at 350° C.

Table 3C and FIG. 7C are shown the difference of the surface resistance and the light transmittance of the composite material AgNps-GNS (5:1)/PU before and after heat treatment at 100° C., wherein the weight proportion of AgNps and GNS is 5:1. The results of Table 3C and FIG. 7C are also shown that, when the electrospinning time of the composite material is less than 120 seconds, the fiber density of the PU substrate is less, so that the stacked structure of graphene will be destroyed by the heat treatment of 100° C., resulting in increased the surface resistance.

When the electrospinning time of the composites is 120 seconds or more, the fiber density of the PU substrate is sufficient to stand the melting of the fibers without affecting the net structure of the graphene. But the sets of the electrospinning time longer than 120 seconds may increase the surface resistance, due to the capillary phenomenon, the excessive polymer fiber after heat treatment may be adsorbed around the graphene to block conductive paths. According to one embodiment of the present disclosure, after heat treatment of 100° C., the surface resistance of the composite material AGNPS-GNS(5:1)/PU has a minimum value, 1.50×10² Ω/□.

In addition, Table 3C and FIG. 7C are shown that the light transmittance of the composite material AgNps-GNS (5:1)/PU after the heat treatment of 100° C. is increased significantly. Since the heat treatment may destroy the structure of the nanofiber substrate to form a uniform film, the light scattering is also disappeared. The electrospinning time is longer, and then the transmittance after heat treatment is increased significantly. For example, when the electrospinning time of the composite material is 120 seconds, the light transmittance before the heat treatment is 79%, and the transmittance after the heat treatment is 85%.

The surface resistances and the light transmittances of the composite material AGNPS-GNS (1:1)/PU and AGNPS-GNS (3:1)/PU are also obtained similar to the above-described results.

FIG. 7D is an image of the composite material the composite material of PU nanofiber before and after the heat treatment according to one embodiment of the present disclosure. In FIG. 7D, the electrospinning time of the composite material is 180 seconds, and the surface of which is milky white before the heat treatment and the surface of which is more transparent significantly after the heat treatment of 100° C.

### Mechanical Properties of M-AgNps-GNS/PU

TABLE 3D
Mechanical Properties of M-AgNps-GNS/PU

| Surface Resistance of | | | |
|---|---|---|---|
| Composite | Content Ratio of Silver | | |
| Material (Ω/□) | Nanoparticles and Graphene | | |
| Bending Angle | 1:1 | 3:1 | 5:1 |
| 0 | 1.95 × 10³ | 2.80 × 10² | 1.50 × 10² |
| 30 | 2.25 × 10³ | 3.90 × 10² | 5.50 × 10² |
| 60 | 4.39 × 10³ | 9.36 × 10² | 3.58 × 10³ |
| 90 | 5.83 × 10³ | 1.33 × 10³ | 6.63 × 10³ |

Table 3D and FIG. 7E are shown the variations of the surface resistance of the different composite material M-AGNPS-GNS (1:1)/PU, M-AGNPS-GNS (3:1)/PU and M-AGNPS-GNS (5:1)/PU in the bent state. The bending angle is the angle between the composite material and the horizontal plane (see the bottom right corner of the FIG. 7E).

The results of Table 3D and FIG. 7E are shown that, because the composite material is bent, the surface resistances of the composite material M-AGNPS-GNS (1:1)/PU and M-AGNPS-GNS (3:1)/PU increase slightly. Compared to the conventional indium tin oxide (ITO) occurring brittle fracture in the bending angle of 60 degrees, the composite material M-AgNps-GNS/PU provided in one embodiment of the present disclosure has excellent flexibility, and may be applied to all known display devices or apparatus.

Conversely, at a bending angle of 60 degrees, the surface resistance of the composite material M-AGNPS-GNS (5:1)/PU increases significantly. Because the silver nanoparticles (AgNps) are gathered excessive to flake, and affect graphene adsorbed on the PU fiber substrate. And at a bending angle of 90 degrees, the level of the increase of the surface resistance of the composite material M-AgNps-GNS(5:1)/PU is up to two orders of magnitude, form 1.50×10² Ω/□ to 6.64×10³ Ω/□.

According to one embodiment of the present disclosure, at a bending angle of 90 degrees, the composite material M-AgNps-GNS(3:1)/PU has the smallest surface resistance, the bending angle is 90 degrees, 1.33×10³ Ω/□.

According to the results of an embodiment of the present disclosure, due to the characteristics of graphene, the graphene layers can be adsorbed on the surface of the nanofiber substrate. And with the organic compound, it helps the graphene layer adsorbed on the nanofiber substrate, and decreases the use of the graphene. Further, a composite material containing the metal nanoparticles has a lower surface resistance, and has excellent flexibility. For the problems met in the known transparent electrodes, the composite structure according to the embodiment of the present disclosure provides a preferred solution, which can be directly applied to various high value-added industries.

The preferred embodiments of the present invention have been disclosed above. However, the manufacturing methods described above are not limited to the embodiment of the present disclosure. The person in the art can modify or transform variously without departing from the spirit and the scope of the present disclosure. Therefore, the protecting scope of the present disclosure should be defined as the following claims.

What is claimed is:

1. A composite structure for a transparent electrode, comprising:
a nanofiber substrate having a light-permeable plane net structure;
a graphene layer disposed on the surface of the light-permeable plane net structure of the nanofiber substrate, the graphene layer including one or more layers of graphene overlapping to each other; and
an organic compound disposed between the nanofiber substrate and the graphene layer, the organic compound having at least a functional group selected from the group consisting of phenyl, pyridyl, pyrimidinyl, carbazolyl, imidazolyl, pyrrolyl, pyrrolidinyl, pyrrolidinone, hydroxyl, carbonyl, amine, secondary amine, tertiary amine, fluorine atom and a combination thereof.

2. The composite structure of claim 1, wherein the nanofiber substrate is a material including Nylon 66, polyurethane, or polystyrene.

3. The composite structure of claim 1, wherein the organic compound is polyvinylpyrrolidone.

4. The composite structure of claim 1, further comprising a metal nanoparticle adsorbed on the graphene layer.

5. The composite structure of claim 4, wherein the metal nanoparticle is made of silver (Ag).

6. A method of manufacturing the composite for the transparent electrode of claim 1, comprising the steps of:
(1) depositing inhomogeneously a nanofiber substrate on a transparent substrate so as to form a light-permeable plane net structure;
(2) mixing a graphene oxide and a organic compound and enabling the graphene oxide to be adsorbed on the organic compound to form a first mixture, wherein the organic compound has at least a functional group selected from the group consisting of phenyl, pyridyl, pyrimidinyl, carbazolyl, imidazolyl, pyrrolyl, pyrrolidinyl, pyrrolidinone, hydroxyl, carbonyl, amine, secondary amine, tertiary amine, fluorine atom and a combination thereof;
(3) enabling the organic compound of the first mixture to be adsorbed, by a non-covalent interaction, on the surface of the nanofiber substrate, wherein the graphene oxide of the first mixture overlaps to each other; and
(4) reducing oxygen-containing groups of the graphene oxide to carbon-carbon double bond (C═C) in the presence of a reducing agent and heat, so as to form the composite for the transparent electrode.

7. The method of claim 6, wherein the non-covalent interaction is one selected from the group consisting of electrostatic interaction, hydrogen-bond interaction, π-π interaction and a combination thereof.

8. The method of claim 6, wherein the step (3) further comprises:
adding a metal compound into the first mixture, so as to form a second mixture bonded with the non-covalent interaction, wherein the metal compound is reduced to be the metal nanoparticle of claim 4; and
forming a conductive network by enabling the second mixture to be adsorbed on the surface of the nanofiber substrate in the light-permeable plane net structure.

9. The method of claim 6, further comprising:
arranging the composite structure for the transparent electrode in an elevated temperature and fusing the nanofiber substrate to form a transparent film.

10. The method of claim 9, wherein the elevated temperature ranges from 100° C. to 350° C.

11. The method of claim 6, wherein the step of depositing is employed by one selected from the group consisting of an electrochemical deposition, a chemical vapor deposition, a magnetron sputtering deposition, a screen printing deposition, a electrospinning deposition, a deposition method of the self-assembled chemical adsorption, a chemical etching, an optical etching, lithography, and a combination thereof.
